(19) United States
(12) Patent Application Publication
(10) Pub. No.: US 2024/0221970 A1
(43) Pub. Date: Jul. 4, 2024

(54) METHOD FOR MANUFACTURING A HEAD FOR IRRADIATING A TARGET WITH A BEAM OF CHARGED PARTICLES

(71) Applicants: UNIVERSITE D’AIX MARSEILLE, Marseille 7 (FR); CENTRE NATIONAL DE LA RECHERCHE SCIENTIFIQUE, PARIS 16 (FR); UNIVERSITE DE TOULON, LA GARDE (FR)

(72) Inventor: Wilfried Vervisch, LANCON PROVENCE (FR)

(21) Appl. No.: 18/004,864

(22) PCT Filed: Jul. 1, 2021
(86) PCT No.: PCT/EP2021/068277

§ 371 Date: Jan. 9, 2023

(30) Foreign Application Priority Data
Jul. 10, 2020 (FR) FR2007366

(51) Int. Cl. G21K 5/04; G21K 1/10; H01J 37/304

(52) U.S. Cl. CPC G21K 5/04; G21K 1/10; H01J 37/304; H01J 2237/24507

(57) ABSTRACT

This method for manufacturing an irradiating head includes:—providing a gun emitting a primary beam of charged particles along a propagation axis, this primary beam having a spatial distribution of charged particles having a median density Dmed₁ of charged particles located at a distance d1 from the propagation axis,—the design and manufacture of a sensor capable of measuring the intensity of a beam of charged particles, this sensor comprising:—an outlet face by means of which a secondary beam of charged particles results having a spatial distribution having a median density Dmed₂ of charged particles, this median density Dmed₂ being located at a distance d₂ from the propagation axis, and—a semiconductor layer. The design of the sensor includes selecting a thickness for the semiconductor layer, wherein the distance d₂ is twice as large as the distance d1.

### CROSS-REFERENCE TO RELATED APPLICATIONS

This application is a national phase entry under 35 U.S.C. § 371 of International Patent Application PCT/EP2021/068277, filed Jul. 1, 2021, designating the United States of America and published as International Patent Publication WO 2022/008358 A1 on Jan. 13, 2022, which claims the benefit under Article 8 of the Patent Cooperation Treaty to French Patent Application Serial No. FR2007366, filed Jul. 10, 2020.

### TECHNICAL FIELD

The disclosure relates to a method for manufacturing a head for irradiating a target with a beam of charged particles, as well as to the irradiation head manufactured by this method.

### BACKGROUND

Irradiation heads are used in many fields, such as radiotherapy, proton therapy, medical imaging, safety or other fields.

These irradiation heads comprise:
a charged particle gun that emits a primary beam of charged particles,
equipment for shaping the primary beam to obtain at the output a secondary beam that differs from the primary beam in terms of its homogeneity and/or its opening angle.

To this end, the shaping equipment typically comprises:
one or more equalizing devices, such as equalizing cones, for increasing the homogeneity of the particles in a cross section of the secondary beam, and
one or more collimators for increasing or, conversely, decreasing the opening angle of the secondary beam.

It is the secondary beam that directly impacts the target to be irradiated.

To control the dose of charged particles applied to the target, the irradiation head also comprises a sensor that measures the intensity of the secondary beam.

The shaping equipment absorbs charged particles and therefore decreases the intensity of the secondary beam. In addition, the shaping equipment is bulky, which increases the size of the irradiation head.

The prior art is also known from WO2017/198630A1, FR2379294A1 and US2019/269940A1.

### BRIEF SUMMARY

Embodiments of the disclosure aim to provide an irradiation head in which the absorption of the charged particles by the shaping equipment is limited and/or in which the size of the shaping equipment is reduced.

Embodiments of the disclosure also relate to a method for manufacturing such an irradiation head (e.g., as claimed in claim 1).

Embodiments of the disclosure also relate to an irradiation head manufactured using the above method.

### BRIEF DESCRIPTION OF THE DRAWINGS

Embodiments of the disclosure will be better understood on reading the following description, provided solely by way of non-limiting example and with reference to the drawings in which:

FIG. 1 is a schematic illustration of the architecture of an irradiation head;

FIG. 2 is a perspective diagram of a spatial distribution of the density of the charged particles in a primary beam;

FIG. 3 is a cross-sectional illustration of the spatial distribution shown in FIG. 2;

FIG. 4 is a perspective diagram of a spatial distribution of the density of charged particles in a secondary beam;

FIG. 5 is a schematic illustration in vertical section of an intensity sensor implemented in the irradiation head of FIG. 1;

FIG. 6 is a flowchart of a method for manufacturing the irradiation head of FIG. 1; and

FIGS. 7 to 9 are diagrams illustrating different spatial distributions of the density of charged particles in a secondary beam.

### DETAILED DESCRIPTION

In the remainder of this description, features and functions well known to those skilled in the art are not described in detail.

In this description, detailed examples of embodiments are first described in chapter I with reference to the figures. Next, in chapter II, variants of these embodiments are presented. Lastly, the advantages of the various embodiments are presented in chapter III.

In this text, the expression “beam of charged particles” denotes ionizing radiation, that is to say a beam capable of producing ions directly or indirectly when it passes through matter.

### Chapter I: Examples of Embodiments

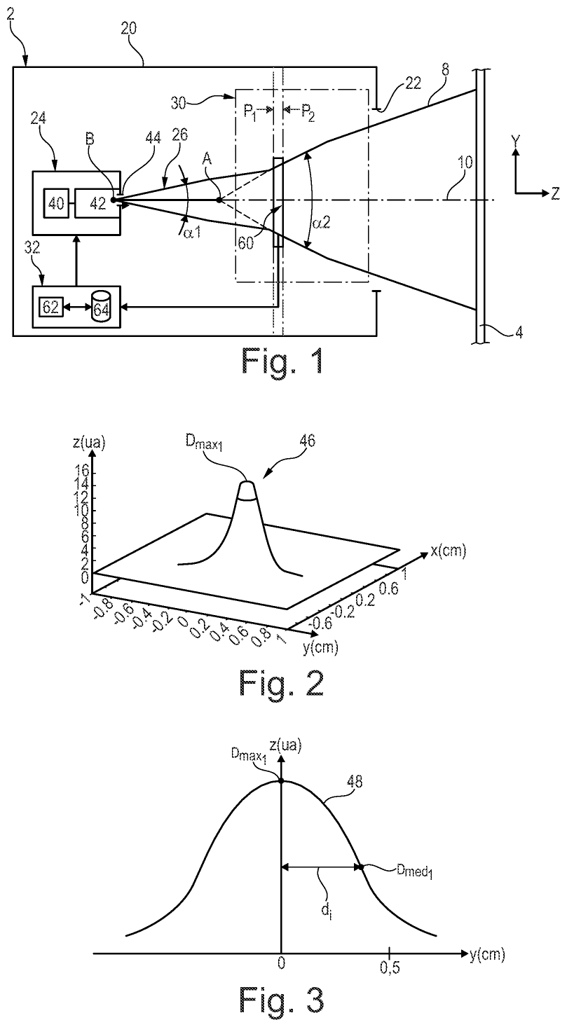

FIG. 1 shows a head 2 for irradiating a target 4 with a secondary beam 8 of charged particles.

The target 4 may be an inert object or part of a human body to be treated using the beam 8.

Between the head 2 and the target 4, the beam 8 propagates along a propagation axis 10 directed toward the target 4. The axis 10 is parallel to a horizontal direction Z of an orthogonal coordinate system XYZ. In this case, the direction Y in this coordinate system is vertical. FIGS. 1 and following are oriented with respect to this coordinate system XYZ.

At the outlet of the head 2, most of the charged particles are included inside a cone that extends along the axis 10. The term “most of the charged particles are included inside this cone” means that 90% or 95% of the charged particles emitted by the head 2 are included inside this cone. For example, this cone is a cone of revolution the axis of revolution of which coincides with the axis 10.

This cone has an apex A situated, in this case, inside the head 2. The solid angle at the apex A is referred to below as the “opening angle” and denoted a2.

The beam 8 is what is referred to as a “high energy” beam, that is to say a beam having an energy greater than or equal to 1 MeV or 10 MeV. In this case, by way of illustration, the energy of the beam 8 is 6 MeV.

The remainder of this description relates to the particular case in which the beam 8 is an electron beam (β-radiation). In such a case, the charged particles are electrons. However, as stated in chapter III, many other beams of charged particles are possible. Herein, the beam 8 is a high-frequency pulsed beam, that is to say a beam that is formed by bursts of pulses repeated at regular intervals at a frequency fₚ. For example, the frequency fₚ is greater than 1 kHz or than 1 MHz or than 100 MHz. Each burst of pulses is formed by a succession of short pulses of charged particles repeated at a frequency f_{z}. The term “high frequency” means that the frequency f_{z} is greater than 1 GHz or 3 GHz and, generally, less than 100 GHz or 10 GHz.

The head 2 comprises a housing 20 inside which are housed and secured together the various components necessary to generate the beam 8. The housing 20 is also designed to insulate the inside of the housing from electromagnetic interference originating from outside this housing. For this purpose, for example, the housing 20 comprises a casing made of conductor materials electrically connected to ground.

The housing 20 comprises an opening 22 through which the beam 8 is emitted. In this case, the space crossed by the beam 8 between the opening 22 and the target 4 is devoid of any equipment capable of modifying the homogeneity or the opening angle of the beam 8. In the absence of such equipment, the characteristics of the beam 8 remain constant over distances of less than 1 m or 50 cm.

The head 2 comprises:
a charged particle gun 24 that generates a primary beam 26 of charged particles,
equipment 30 for shaping the beam 26, for converting the latter into a beam 8, and
a unit 32 for controlling the gun 24.

The head 2 differs from known irradiation heads essentially by virtue of the equipment 30. Therefore, the other components of the head 2 are not described in detail below.

The gun 24 comprises:
a source 40 of charged particles that produces the charged particles,
an acceleration chamber 42 that accelerates the charged particles produced by the source 40, and
a firing window 44 through which the beam 26 is emitted.

The amount of charged particles produced by the source 40 is controllable. This makes it possible notably to adjust the dose of charged particles delivered on the target 4.

Typically, the chamber 42 accelerates the charged particles produced using electromagnetic fields for this purpose. For example, the gun 24 is a gun known by the acronym LINAC (Linear Particle Accelerator).

The beam 26 is a beam identical to the beam 8 except that:
its apex B is located, for example, inside the gun 24,
its opening angle α₁ is different from the angle α₂, and
the spatial distribution of the charged particles in a cross section of the beam 26 is different from the spatial distribution of the charged particles in a cross section of the beam 8.

The charged particles of the beam 26 are the same as those of the beam 8.

For example, the angle α₁ is two, four or six times smaller than the angle α₂.

An example of a spatial distribution 46 of the charged particles in a cross section of the beam 26 is shown in FIG. 2. A “cross section” of the beam is a section through the beam along a plane perpendicular to its propagation axis. In this case, the spatial distribution 46 corresponds to the spatial distribution of the charged particles in a plane P₁ located inside the housing 20 between the apex B and the inlet of the shaping equipment 30. Typically, this plane P₁ is located less than 50 cm or less than 10 cm from the firing window 44. In this case, the plane P₁ is located 5 cm from the firing window 44.

The spatial distribution 46 shows the density of charged particles at each point of the plane P₁. To this end, the axes x and y of the spatial distribution 46 correspond to the x-axis and y-axis, respectively. These axes x and y are contained in the plane P₁. In this case, the axes x and y are parallel to the directions X and Y of the coordinate system XYZ, respectively. In FIG. 2, these axes x and y are graduated in centimeters. The axis 10 passes through the plane P₁ at the coordinate point 0 cm on the x-axis and 0 cm on the y-axis. The axis z in FIG. 2, which is perpendicular to the axes x and y, represents the density of charged particles per cm². In this case, the axis z is graduated in an arbitrary unit “ua” proportional to the density of charged particles per cm². This unit ua is the same in all figures showing a spatial distribution of charged particles.

As illustrated by the spatial distribution 46, the density of charged particles has a maximum, denoted Dmax₁, at the axis 10. This density then gradually and continuously decreases moving away from the axis 10 until it reaches a zero or practically zero value outside the cone containing most of the charged particles of the beam. For example, in the case of the beam 26, the density Dmax₁ is equal to 16 ua.

The spatial distribution 46 is symmetrical about the axis 10. Thus, the way in which the density of the charged particles decreases moving away from the axis 10 in a predetermined direction contained in the plane P₁ is the same regardless of this predetermined direction.

Conventionally, the spatial distribution 46 has a Gaussian geometry. In other words, when a section through the spatial distribution 46 is observed along a plane containing the axis 10, a bell-shaped curve 48 (FIG. 3) is obtained. In FIG. 3, the curve 48 is that obtained along a sectional plane perpendicular to the axis x of the x-axis. More specifically, the curve 48 is in this case, for example, a Gaussian function.

The curve 48 shows the homogeneity of the spatial distribution of the charged particles in the plane P₁. More specifically, in this text, the homogeneity of the spatial distribution of the charged particles is represented by a physical magnitude referred to as “distance” and denoted d₁ in the plane P₁. The distance d₁ is the distance, expressed in centimeters, which separates the axis 10 from the point of the plane P₁ where the density of the charged particles is equal to Dmed₁. The density Dmed₁ is the median density of the charged particles, that is to say the density equal to Dmax₁/2. The greater the distance d₁, the better the homogeneity of the spatial distribution of the charged particles in the plane P₁. In addition, the greater the distance d₁, the greater the angle α₁. Conventionally, the homogeneity of the beam 26 is poor. For example, in this case, the distance d₁ is less than 0.5 cm and the angle α₁ is small.

The equipment 30 is interposed, along the axis 10, between the firing window 44 and the opening 22, to modify the homogeneity and the opening angle of the beam 26 so as to obtain the beam 8 that has a desired homogeneity and the opening angle α₂. The desired homogeneity and the opening angle α₂ are predetermined characteristics imposed by the user of the head 2. These characteristics are therefore data known in advance and hence even before the design of the head 2.

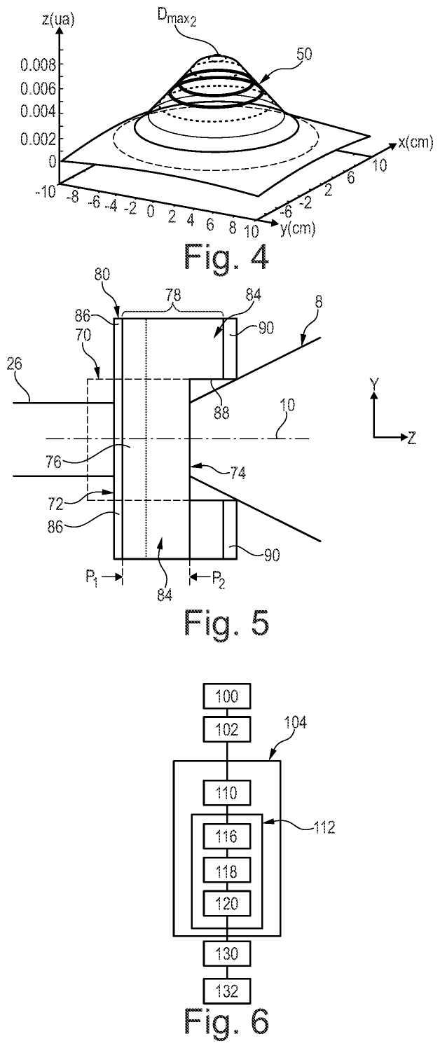

By way of illustration, FIG. 4 shows a spatial distribution 50 of the charged particles for the beam 8. The spatial distribution 50 is identical to the spatial distribution 46 except that:
the maximum density at the axis 10 is denoted Dmax₂,
the median density is denoted Dmed₂, and
the distance separating the axis 10 from the point where the density of charged particles is equal to Dmed₂ is denoted d₂.

In other words, the distance d₂ is defined as the distance d₁ except that it is measured in the spatial distribution of the beam 8. In FIG. 4, Dmax₂ is of the order of 0.0008 ua.

In this case, the homogeneity of the beam 8 is at least twice or four times or ten times greater than the homogeneity of the beam 26. Thus, the distance d₂ is twice, four times or ten times greater than the distance d₁.

In this first embodiment, to shape the beam 26 in order to obtain the beam 8, the equipment 30 comprises only a sensor 60 for detecting the intensity of the beam 8. In other words, between the firing window 44 of the gun 24 and the sensor 60 and between the sensor 60 and the opening 22, the head 2 has no other shaping equipment such as an equalizing device or a collimator, capable of modifying the homogeneity and/or the opening angle of the beam 8.

The architecture and the design of the sensor 60 are described in more detail with reference to FIGS. 5 and 6 below.

The sensor 60 transmits the measured intensity of the beam 8 to the control unit 32. For example, to this end, the sensor 60 is connected, by means of a wired link, to the unit 32.

The unit 32 controls the gun 24 as a function of the intensity of the beam 8 measured by the sensor 60. Typically, the unit 32 controls the gun 24 so as to maintain the dose of charged particles applied to the target 4 equal to or practically equal to a pre-recorded setpoint Cd. For example, to this end, the unit 32 controls the source 40 as a function of a difference between the measured intensity of the beam 8 and an intensity setpoint. To this end, the unit 32 comprises a microprocessor 62 and a memory 64. The memory 64 includes instructions executed by the microprocessor 62 to control the gun 24.

FIG. 5 shows in more detail a possible example of an arrangement of the sensor 60. In this example of an embodiment, the architecture of the sensor 60 is identical to that described with reference to FIG. 2 of application WO 2017198630. Thus, for more detail on the architecture of the sensor 60, the reader can consult this application.

The sensor 60 is a semiconductor sensor. More specifically, the sensor 60 comprises an active area 70 able to generate electrical charges when charged particles pass through it. To this end, the area 70 is located on the axis 10. In this case, it is centered on the axis 10. More specifically, in this embodiment, the area 70 is a cylinder of revolution the axis of revolution of which coincides with the axis 10.

The area 70 has an input face 72 located in the plane P₁ and directly exposed to the beam 26. The area 70 also comprises an output face 74 located in a plane P₂ perpendicular to the axis 10. The beam 26 emerges from the sensor 60 via the face 74 and forms the beam 8. In the plane P₂, the spatial distribution of the charged particles is, for example, that shown in FIG. 4.

The area 70 comprises a depletion region 76 also referred to as a “space charge region”. This region 76 produces charge carriers of a first type and charge carriers of a second type when it is crossed by the charged particles of the beam 26. This region 76 is located between the face 72 and a boundary represented by a dotted line parallel to the direction Y in FIG. 5.

To this end, in this example, the area 70 comprises a semiconductor layer 78 and a conductor layer 80 directly deposited on the face of the layer 78 facing the gun 24. The face 72 is in this case formed by the outer face of the layer 80 facing the gun 24. The face 74 of the area 70 is formed by the face of the layer 78 facing the target 4. The thickness eᵢ of the layer 78 is the distance, along the axis 10, between its two opposite faces. In this case, this thickness is constant inside the entire area 70.

The region 76 is located in the region of the layer 78 in contact with the conductor layer 80. The combination of layers 78 and 80 forms a junction with a rectifier effect and, more specifically, a “Schottky diode” in this embodiment.

The semiconductor material used to produce the layer 78 comprises two energy bands known under the terms “valence band” and “conduction band”, respectively. In the case of semiconductor materials, these two energy bands are separated from one another by a bandgap or “gap”. Preferably, the semiconductor material used to produce the layer 78 is a wide bandgap semiconductor material, that is to say a semiconductor material having a bandgap the value of which is at least twice the value of the bandgap of silicon. Typically, the bandgap of the semiconductor material used for the layer 78 is therefore greater than 2.3 eV.

In this case, the layer 78 is made of silicon carbide SiC-4H. In this description, the expression “an element made of X material” means that the X material represents at least 70% or 80% or 90% of the mass of this element. In this case, the semiconductor layer 78 is additionally doped. For example, when the semiconductor layer 78 is made of silicon carbide, P doping can be obtained by implanting boron atoms and, alternatively, N doping can be obtained by implanting nitrogen atoms.

The conductor layer 80 is made of, for example, metal such as copper, zinc or gold.

In this embodiment, the layers 78 and 80 extend transversely beyond the area 70 to form a peripheral portion 84 that completely surrounds the active area 70. Unlike the area 70, the peripheral portion 84 is not crossed by the beam of charged particles. The portion 86 of the conductor layer 80 that extends beyond the area 70 forms a first electrode that collects the charge carriers of the first type produced by the region 76.

In this case, the thickness of the semiconductor layer 78 in the peripheral portion 84 is greater than the thickness eᵢ, such that it forms the side walls of a blind hole 88 the bottom of which is coincident with the face 74. The orthogonal projection of the side wall of the hole 88 onto the plane P₂ completely surrounds the face 74.

Lastly, only in the peripheral portion 84, the face of the semiconductor layer 78 that faces the target 4 is covered with a conductor layer 90. The conductor layer 90 is made of, for example, the same conductor material as the conductor layer 80. The conductor layer 90 forms a second electrode that collects charge carriers of the second type produced by the region 76.

For example, the face 74 is structured as described in application WO2017198630A1. Likewise, metal beads may be introduced into the semiconductor layer 78 as described in this same patent application.

The method for manufacturing the head 2 will now be described with reference to FIG. 6.

Initially, during a step 100, the various characteristics of the beam 8 that is to be generated by the head 2 are acquired. These characteristics notably include the type of charged particles and the energy range of the beam 8.

Next, during a step 102, a gun 24 capable of generating a beam with the same charged particles and over an energy range that encompasses the energy range desired for the beam 8 is provided. For example, this gun 24 is constructed or purchased. Consequently, at this stage, the various characteristics of the beam 26 are known. In particular, its angle α1 and the distance d₁ are thus known or determinable.

Then starts a phase 104 of designing and manufacturing the sensor 60 so that alone it fulfills at the same time:
the function of measuring the intensity of the beam 8, and
the function of shaping equipment for converting the beam 26 into the beam 8.

At this stage, it is specified that in the prior art, it has never been imagined that a semiconductor sensor can, alone, substantially modify the homogeneity and the opening angle of the beam of charged particles that passes through it. In this case, “substantially modified” means a modification that makes it possible to obtain a distance d₂ that is at least twice and, preferably, at least four or ten times greater than the distance d₁. On the contrary, in the prior art, the thickness eᵢ is systematically chosen as small as possible to maximize the transmission rate of the sensor. The transmission rate of a sensor is equal to the ratio Iₒᵤₜ/Iᵢₙ, in which Iₒᵤₜ and Iᵢₙ are the intensities of the beams exiting and entering the sensor, respectively. However, such a sensor with a semiconductor of very small thickness eᵢ does not substantially modify the homogeneity of the beam passing through it.

In this case, this idea is exploited to design a sensor 60 that, alone, makes it possible to convert the beam 26 into a beam 8 without the aid of additional equipment for shaping the beam.

To this end, during a step 110, the semiconductor material from which the semiconductor layer 78 is to be produced is first selected from the list of semiconductor materials that are good candidates for manufacturing the active area 70. In this case, this semiconductor material is silicon carbide SiC-4H. At this stage, the various characteristics of the chosen semiconductor material are therefore known. In particular, the density of the chosen material is known.

Next, during a step 112, the thickness eᵢ of the semiconductor layer 78 is adjusted so that the spatial distribution of the charged particles of the beam 8 in the plane P₂ is substantially modified relative to the spatial distribution 46 of the beam 26 in the plane P₁. Thus, in this case, at least, the thickness eᵢ is adjusted so that the distance d₂ is at least twice the distance d₁.

For this purpose, several possible values of thickness eᵢ are successively trialed, until one or more thicknesses eᵢ are obtained that satisfy various selection criteria. Among these different selection criteria, at least one of them systematically leads to the selection of a value for the thickness eᵢ such that the distance d₂ is greater than twice the distance d₁. In this case, this first selection criterion is as follows:
criterion 1): the thickness eᵢ selected corresponds to a distance d₂ above a threshold dmin₂, where the threshold dmin₂ is greater than twice the distance d₁.

For example, during an operation 116, several possible values of the thickness eᵢ are chosen. The values are chosen within an interval [eminᵢ; emaxᵢ] and are spaced apart from one another by a pitch, which is, for example, regular. The value eminᵢ, is, for example, greater than or equal to the minimum thickness that the semiconductor layer 78 must have so as to allow the measurement of the intensity of the beam 8. The value emaxᵢ is five, or ten or fifty times greater than the value eminᵢ. Generally, the value emaxᵢ is less than 1 cm or 5 mm. For example, in this case, the value eminᵢ is equal to 50 μm, while the minimum value of the thickness eᵢ that makes it possible to measure the intensity of the beam 8 is more of the order of 10 μm. In this case, the value emaxᵢ is equal to 1 mm.

The regular pitch is chosen so that the number of trials to be carried out is reasonable. For example, the pitch chosen is 50 μm.

Next, during an operation 118, the value of the distance d₂ corresponding to each of the values of the thickness eᵢ chosen during the operation 116 is determined. In this case, in addition, during the operation 118, the value of the angle α₂ and of the transmission rate T2 of the sensor 60 corresponding to each of the values selected for the thickness eᵢ, are also determined.

To this end, for each value of the thickness eᵢ selected, the spatial distribution of the charged particles of the beam in the plane P₂ is first constructed by digital simulation. For example, such a digital simulation is carried out using MCNP (Monte-Carlo N-Particle transport code) software or Geant (GEometry ANd Tracking) software. These software programs make it possible to model the beam 26 and the active area 70. Next, by implementing Monte-Carlo simulations, they construct the spatial distribution of the charged particles in any plane of which the location along the axis 10 is specified. Thus, to obtain the spatial distribution in the plane P₂, the position and the various characteristics of the beam 26 and of the layers 78 and 80 are modeled and entered into this software. The characteristics of the beam 26 are those chosen during steps 100 and 102. The positions of the planes P₁ and P₂ are also specified. During the simulation, the following characteristics are also entered into the simulation software:
the characteristics of the semiconductor material used to produce the semiconductor layer 78, notably its density and its thickness eᵢ,
optionally, the characteristics of the conductor material used to produce the conductor layer 80, notably its density and its thickness, and
the position of the sensor 60 relative to the firing window 44 as previously described with reference to FIG. 1.

Lastly, in addition to the spatial distribution of the charged particles in the planes P₁ and P₂, these software packages also make it possible to determine at the same time:
the intensities Iₒᵤₜ and Iᵢₙ of the beam of charged particles in the planes P₁ and P₂, respectively,
the opening angle of the beam 8.

Once the spatial distribution of the beam in the plane P₂ is constructed, the value of the distance d₂ is then determined. To this end, for example:
the maximum density Dmax₂ is read at the coordinate point (0 cm; 0 cm), then
the median density Dmed₂ is calculated using the following relationship: Dmed₂=Dmax₂/2, then
the coordinates of a point where the density of charged particles is equal to the density Dmed₂ are read, and finally,
the distance between this read point and the coordinate point (0 cm; 0 cm) is calculated.

This calculated distance is the distance d₂ of the spatial distribution of the beam in the plane P₂.

Such a digital simulation also makes it possible to determine the number of charged particles that pass through the planes P₁ and P₂ over a predetermined period of time. The intensities Iₒᵤₜ and Iᵢₙ are then deduced from this information.

The opening angle of the simulated beam 8 that emerges via the face 74 is also determined.

Each time a specific value of the thickness eᵢ is simulated, this specific value is recorded in a row of a result table and the values of the distance d₂, the rate T₂ and the angle α₂ corresponding to this thickness are recorded in the same row.

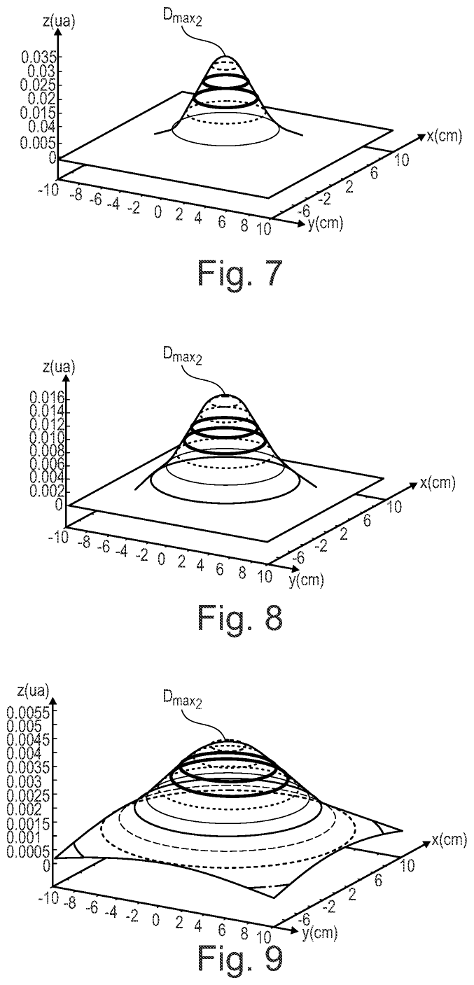

FIG. 4 is a first example of a spatial distribution obtained by digital simulation when the thickness eᵢ is taken to be equal to 200 μm. FIGS. 7 to 9 show spatial distributions that are identical except that they are obtained for thicknesses eᵢ equal to 50 μm, 100 μm and 300 μm, respectively. As shown in FIGS. 4 and 7 to 9, the distance d₂ greatly increases as a function of the thickness eᵢ.

Next, during an operation 120, the value of the thickness eᵢ to be used to manufacture the sensor 60 is selected from the various values simulated during the operation 118. For this purpose, in this case, in addition to selection criterion 1), additional selection criteria are used. More specifically, the following two additional selection criteria are used:
criterion 2): the thickness eᵢ must correspond to a transmission rate T₂ above a threshold Tₘᵢₙ₂, and
criterion 3): the thickness eᵢ must correspond to a value of the angle α₂ above a threshold αmin₂.

For example, the threshold Tₘᵢₙ₂ is greater than 0.4 or 0.5 and, preferably, greater than 0.7 or 0.9. The threshold αmin₂ is, for example, greater than two or four or ten times the angle α₁.

The order of priority between the three criteria 1) to 3) is in this case as follows: criterion 1) is higher than criterion 2), criterion 2) is higher than criterion 3).

Consequently, the various values of the thickness eᵢ in the result table that satisfy criterion 1) are selected first. Next, if there are several values of the thickness eᵢ that satisfy criterion 1), only the values of the thickness eᵢ that also satisfy criterion 2) are selected.

If at this stage there are still several possible values of the thickness eᵢ that satisfy both criteria 1) and 2), then among the set of these possible values, only the values of the thickness eᵢ that also satisfy criterion 3) are selected.

Finally, if at this stage there are still several possible values of the thickness eᵢ that satisfy all of criteria 1) to 3), only one of them is selected. For example, it is the smallest of these values that is selected.

The adjustment of the thickness eᵢ is thus complete. The other operations involved in design of the sensor 60 are, for example, conventional and are not described herein.

The phase 104 of design of the sensor 60 is thus complete. For example, in this case, it is the thickness eᵢ equal to 200 μm that has been selected for manufacture of the head 2.

In a step 130, the sensor 60 designed during phase 104 is manufactured. During this step, the semiconductor layer 78 is produced such that it has the thickness eᵢ selected in operation 120.

Next, during a step 132, the irradiation head 2 is manufactured. To this end, the gun 24 provided in step 102 and the sensor 60 manufactured in step 130 are assembled and secured inside the housing 20 to obtain the arrangement described in detail with reference to FIG. 1.

### Chapter II: Variants

### Variants of the Sensor:

Many other embodiments of the sensor 60 are possible. For example, the depletion region 76 may also take the form of a PN diode or a PIN diode or the depletion region of a field-effect transistor. In particular, the various architectures of a semiconductor sensor described in application WO2017198630A1 can be implemented to design a semiconductor sensor capable of being used instead of the sensor 60 and fulfilling the same functions.

As a variant, the blind hole 88 is omitted.

Materials other than silicon carbide are possible to produce semiconductor layer 78. For example, as a variant, the semiconductor layer 78 is made of diamond or a semiconductor alloy composed of elements from column III-V or II-VI.

The conductor layers 80, 90 may be made of conductor materials other than a metal. For example, as a variant, they are made of single-layer or multilayer graphene. They may also be made of other metals such as nickel, aluminum, titanium or tungsten. The layers 80 and 90 are not necessarily made of the same conductor materials.

The structuring of the face 74 may be omitted. Likewise, the incorporation of metal beads into the semiconductor layer 78 may also be omitted.

Variants of the manufacturing method:

The layer 80 has little influence on the spatial distribution of the charged particles in the plane P₂. Thus, in a simplified variant, only the layer 78 is modeled in the simulation software. Likewise, it is not necessary to model the portions of the sensor 60 through which the beam does not pass, such as, for example, the peripheral portion 84.

As a variant, spatial distributions are not determined by digital simulation but experimentally. For example, for this purpose, a grid of sensors is placed in the plane P₁. These sensors are arranged, for example, at regular intervals in the X and Y directions. Each sensor locally measures the intensity of the beam of charged particles at the location where it is situated. The intensity of the beam of charged particles at a particular location depends on the number of charged particles received over a period of time at that location and therefore on the density of charged particles at that location. This sensor grid therefore makes it possible to measure the spatial distribution of the charged particles in the plane containing this sensor grid. Next, a semiconductor layer 78 of chosen thickness eᵢ is placed between the planes P₁ and P₂ and the sensor grid is placed in the plane P₂, that is to say just behind the semiconductor layer trialed. In this case, no sensor grid is placed upstream of the semiconductor layer, that is to say on the side facing the gun 24. In this configuration, the sensor grid makes it possible to measure the spatial distribution of the charged particles in the plane P₂ in the presence of the semiconductor layer. Next, the process is carried out as described above, in other words different thicknesses of the semiconductor layer are successively trialed until the right thickness is found. It is also possible to use a single sensor instead of a grid of several sensors. In the latter case, this single sensor is moved in the plane in which it is desired to detect the spatial distribution of the charged particles in order to measure the intensity of the beam at different locations in this plane.

Other embodiments of the operation for selecting the thickness eᵢ to be used to manufacture the sensor 60 are possible. As a variant, additional criteria may be taken into account to select the value of the thickness eᵢ to be used. For example, an additional criterion may be to impose that the value of the thickness eᵢ be less than a maximum threshold in order to take into account manufacturing constraints.

Conversely, the number of selection criteria may also be reduced. For example, as a variant, one of criteria 2) and 3) is omitted or replaced by another criterion. When criteria 2) and 3) are omitted, the determination during operation 118 of the transmission rate T₂ and/or of the value of the angle α₂ may thus be omitted.

The order of priority between the various selection criteria may also be modified. For example, the priority of criterion 3) may be higher than that of criterion 1) or 2).

Criterion 3) may be replaced or supplemented by a criterion that imposes a maximum value on the angle α₂.

Physical magnitudes other than the distance d₁ or d₂ may be used as a measure of the homogeneity of a spatial distribution of charged particles. However, irrespective of the physical magnitude used, this is representative of a distance d₁ or d₂. Typically, there is a one-to-one correspondence between the values of this physical magnitude and the values of the distance d₁ or d₂. For example, a physical magnitude representative of the distance d₁ or d₂ is the standard deviation or the variance of the spatial distribution. The standard deviation of the spatial distribution is, for example, calculated from data of a cross section of the spatial distribution as shown in FIG. 3. The ratio Dmax₂/Dmax₁ is also a physical magnitude representative of the homogeneity of the spatial distribution. To be specific, the smaller this ratio, the greater the homogeneity of the secondary spatial distribution compared to the primary spatial distribution. Similarly, distances other than the distance d₁ or d₂ may be used. For example, it is possible to use a distance d′ between the axis 10 and a point where the density of charged particles is equal to a predetermined density D₂, where the density D₂ is less than the density Dmax₂ and different from the density Dmed₂. It is also possible to use a distance between two points corresponding to two different predetermined densities D₂ and D₃, respectively, where the density D₃ is different from density D₂.

Other variants:

As a variant, the cross section of the beam 8 is not necessarily circular. In other words, the cone that delimits the beam 8 at the outlet of the head 2 is not necessarily a cone of revolution.

The manufacturing method described herein also applies to the manufacture of irradiation heads for beams of charged particles of lower energy and notably for beams of charged particles with an energy less than 1 MeV or 100 keV or 10 keV.

The beam is not necessarily an electron beam. The manufacturing method described herein applies to any type of beam of charged particles. For example, the charged particles belong to the group consisting of electrons, positrons, protons and heavy charged particles. Heavy charged particles comprise all particles comprising a core. For example, these are a particles, carbon ions, copper ions or gold ions.

To be specific, for any selected charged particles, for any semiconductor material selected for the layer 78 and for any energy selected for the beam 26, there is at least one thickness eᵢ that makes it possible to substantially modify the spatial distribution of the beam 26. However, if step 112 leads to the selection of a thickness eᵢ that is not compatible with other manufacturing constraints, such as, for example, the size of the sensor 60, then one of the previous choices may be modified before reiterating step 112. For example, another semiconductor material is selected for the layer 78.

In another embodiment, the beam 8 is not a pulsed beam but a continuous beam.

The control unit 32 may also be placed outside the housing 20.

As a variant, the equipment 30 comprises, in addition to the sensor 60, an equalizing device and/or a collimator. In this case, this equalizing device and/or this collimator is preferably placed upstream of the sensor 60. In this variant, since the sensor is designed to perform part of the beam shaping work, the equalizing device and/or the collimator are simpler and less bulky.

### Chapter III: Advantages of the Embodiments Described

The choice of a thickness eᵢ for the semiconductor layer that makes it possible to improve the homogeneity of the beam of charged particles by a factor of at least two makes it possible to simplify the irradiation head. For example, when the semiconductor sensor makes it possible to achieve the desired homogeneity of the beam 8 without any equalizing device other than the sensor itself, then this limits the bulk of the irradiation head. In fact, no additional equalizing device is necessary. In addition, when an equalizing device other than the sensor is used in an irradiation head, it absorbs part of the particles of the beam 8. Thus, the irradiation head described herein, by doing away with any additional equalizing device, also limits the problem of absorption of the charged particles by these additional equalizing devices.

In the case where the thickness of the semiconductor layer of the sensor does not make it possible to achieve the desired homogeneity or the desired opening angle for the beam 8, an additional equalizing device or an additional collimator may be used in addition to the sensor. However, even in this case, the use of the sensor described herein makes it possible to simplify this equalizing device or this collimator, since a substantial part of the work of shaping the beam of charged particles is carried out by the sensor. Thus, the number and/or the structure of the additional equalizing device and/or of the additional collimator are simplified. Consequently, even in the latter case, the sensor described herein makes it possible to simplify the irradiation head and therefore to limit its bulk while at the same time limiting the problem of absorption of charged particles by the shaping equipment.

The determination by digital simulation of the spatial distribution simplifies the implementation of the method for manufacturing the irradiation head.

The selection of the thickness of the semiconductor layer so as to increase the transmission rate of the sensor makes it possible to obtain a sensor that is highly transparent to the beam of charged particles while being capable of substantially homogenizing this beam of charged particles.

The selection of the thickness of the semiconductor layer in such a way as to substantially increase the opening angle of the beam of charged particles makes it possible to obtain a sensor that both substantially increases the opening angle while being capable, at the same time, of substantially homogenizing the beam of charged particles.

1. A method for manufacturing a head for irradiating a target with a beam of charged particles, this method comprising:
providing a charged particle gun comprising a firing window from which a primary beam of charged particles is emitted along a propagation axis, said primary beam of charged particles having a primary spatial distribution of charged particles in a first plane perpendicular to the propagation axis and located at a predetermined distance from the firing window, this primary spatial distribution comprising a maximum density Dmax₁ of charged particles on the propagation axis and a median density Dmed₁ of charged particles equal to half the maximum density Dmax₁, this median density Dmed₁ being located at a distance d₁ from the propagation axis in a first direction perpendicular to the propagation axis,
designing and manufacturing a sensor capable of measuring the intensity of a beam of charged particles, this sensor comprising:
an active area capable of interacting with the charged particles to produce electrical charges when this active area is crossed by the beam of charged particles, this active area comprising:
an inlet face which extends in the first plane and which is centered on the propagation axis,
an outlet face via which the beam of charged particles which is received on the inlet face emerges, the beam which emerges from this outlet face being referred to as the “secondary beam”, this outlet face extending in a second plane parallel to the first plane, the secondary beam of charged particles having a secondary spatial distribution in the second plane, this secondary spatial distribution comprising a maximum density Dmax₂ of charged particles on the propagation axis and a median density Dmed₂ of charged particles equal to half the maximum density Dmax₂, this median density Dmed₂ being located at a distance d₂ from the propagation axis in the first direction,
a semiconductor layer interposed between the inlet and outlet faces and parallel to these inlet and outlet faces, and
electrodes for sensing the electrical charges produced by the active area, the intensity of the current between these electrodes being representative of the intensity of the beam of charged particles passing through this sensor,
designing the sensor comprising:
selecting the semiconductor material used to produce the semiconductor layer, and
adjusting the thickness of the semiconductor layer,
wherein adjusting the thickness of the semiconductor layer comprises selecting a thickness for which the distance d₂ is twice the distance d₁.

2. The method as claimed in claim 1, wherein adjusting the thickness of the semiconductor layer comprises:
choosing several possible thicknesses for the semiconductor layer, then
for each of the chosen thicknesses, determining, by experimentation or by simulation, a physical magnitude representative of the distance d₂, then
selecting, from the different chosen possible thicknesses, a thickness for which the determined physical magnitude corresponds to a distance d₂ which is twice the distance d₁.

3. The method as claimed in claim 2, wherein determining the physical magnitude comprises determining, by digitally simulating, the secondary spatial distribution and then calculating the value of the physical magnitude from the spatial distribution determined.

4. The method as claimed in claim 3, wherein the digital simulation is performed using MCNP (Monte-Carlo N-Particle transport code) software or Geant (GEometry ANd Tracking) software.

5. The method as claimed in claim 1, wherein adjusting the thickness of the semiconductor layer comprises selecting a thickness for which the distance d₂ is four times greater than the distance d₁.

6. The method as claimed in claim 1, wherein adjusting the thickness of the semiconductor layer comprises selecting (120) a thickness for which, in addition, the ratio Iₒᵤₜ/Iᵢₙ is greater than 0.5 or 0.7 or 0.9, where Iᵢₙ and Iₒᵤₜ are the intensities of the primary and secondary beams, respectively.

7. The method as claimed in claim 6, wherein the intensities Iᵢₙ and Iₒᵤₜ are established on the basis of the primary and secondary spatial distributions, respectively.

8. The method as claimed in claim 1, wherein adjusting the thickness of the semiconductor layer comprises selecting a thickness for which, in addition, the solid angle of the secondary beam is twice the solid angle of the primary beam.

9. The method as claimed in claim 1, wherein the method further comprises determining, by experimentation or by simulation, the physical magnitude representative of the distance d₁.

10. A head for irradiating a target with a beam of charged particles, manufactured by a method as claimed in claim 1, said irradiation head comprising:
a charged particle gun comprising a firing window from which a primary beam of charged particles is emitted along a propagation axis, said primary beam of charged particles having a primary spatial distribution of charged particles in a first plane perpendicular to the propagation axis and located at a predetermined distance from the firing window, this primary spatial distribution comprising a maximum density Dmax₁ of charged particles on the propagation axis and a median density Dmed₁ of charged particles equal to half the maximum density Dmax₁, this median density Dmed₁ being located at a distance d₁ from the propagation axis in a first direction perpendicular to the propagation axis,
a sensor capable of measuring the intensity of the beam of charged particles, this sensor comprising:
an active area capable of interacting with the charged particles to produce electrical charges when this active area is crossed by the beam of charged particles, this active area comprising:
an inlet face which extends in the first plane and which is centered on the propagation axis,
an outlet face via which the beam of charged particles which is received on the inlet face emerges, the beam which emerges from this outlet face being referred to as the “secondary beam”, this outlet face extending in a second plane parallel to the first plane, the secondary beam of charged particles having a secondary spatial distribution in the second plane, this secondary spatial distribution comprising a maximum density Dmax₂ of charged particles on the propagation axis and a median density Dmed₂ of charged particles equal to half the maximum density Dmax₂, this median density Dmed₂ being located at a distance d₂ from the propagation axis in the first direction,
a semiconductor layer interposed between the inlet and outlet faces and parallel to these inlet and outlet faces, and
electrodes for sensing the electrical charges produced by the active area, the intensity of the current between these electrodes being representative of the intensity of the beam of charged particles passing through this sensor,
wherein the thickness of the semiconductor layer is adjusted so that the distance d₂ is twice the distance d₁.

11. The head as claimed in claim 10, wherein the head does not have any an additional device for homogenizing the density of charged particles of the beam of charged particles located, along the propagation axis, upstream or downstream of the sensor.

12. The head as claimed in claim 10, wherein the active area comprises a junction with a rectifier effect capable of switching between:
an on state in which the junction allows a current to pass in one direction, and
an off state in which the junction opposes the passage of the current in the opposite direction.
